(19) United States
(12) Patent Application Publication
(10) Pub. No.: US 2025/0351622 A1
(43) Pub. Date: Nov. 13, 2025

(54) LIGHT-EMITTING DIODE, LIGHT-EMITTING SUBSTRATE, AND DISPLAY DEVICE

(71) Applicant: HUIZHOU CHINA STAR OPTOELECTRONICS DISPLAY CO., LTD., Huizhou, (CN)

(72) Inventor: Jiao WANG, Huizhou (CN)

(21) Appl. No.: 17/769,360

(22) PCT Filed: Apr. 13, 2022
(86) PCT No.: PCT/CN2022/086544

§ 371 Date: Jan. 27, 2025

(30) Foreign Application Priority Data
Mar. 21, 2022 (CN) 202210280204.X

(51) Int. Cl. H10H 20/819; G02F 1/13357; H01L 25/075; H10H 20/84; H10H 29/24; H10H 29/85; H10H 29/853

(52) U.S. Cl. CPC H10H 20/819; G02F 1/133603; H10H 20/84; H10H 29/24; H10H 29/8508; H10H 29/853; H01L 25/0753

(57) ABSTRACT

The present application provides a light-emitting diode, a light-emitting substrate, and a display device. The light-emitting diode includes a first semiconductor layer, a light-emitting layer, a second semiconductor layer, and a first protective layer arranged in sequence. A surface of the second semiconductor layer away from the light-emitting layer is a first diffusion surface, the first diffusion surface includes a first central curved surface and a first edge curved surface connected to the first central curved surface, the first central curved surface is concave towards the light-emitting layer, and the first edge curved surface is convex towards the light-emitting layer.

### BACKGROUND OF INVENTION

### Field of Invention

The present application relates to a field of display technology, and more particularly to a light-emitting diode, a light-emitting substrate, and a display device.

### Description of Prior Art

A mini light-emitting diode (mini LED) display technology can be applied not only to a direct display product, but also to a mini LED backlight product. When mini LED display technology is applied to the backlight product and equipped with a liquid crystal display (LCD) at a same time, it can create a backlight that can realize partition control, it is a high-end display product with a contrast ratio similar to that of an organic light-emitting diode (OLED) display.

Different from a backlight product in a traditional LCD, the mini LED display technology can make backlight lamp beads very small, so that more backlight lamp beads can be integrated on a same screen, which can be divided into finer backlight partitions improving contrast of the backlight product and improving backlight sense.

However, light-emitting viewing angle of existing LEDs is relatively small, and number of LEDs is relatively high under a condition of ensuring a same backlight sense. Therefore, providing an LED of wide-angle light emission to reduce production cost of backlight products has become an urgent technical problem to be solved.

### SUMMARY OF INVENTION

The present application provides a light-emitting diode, a light-emitting substrate, and a display device. By providing the light-emitting diode of a wide-angle light emission, the number of LEDs in a backlight product can be reduced under the condition of ensuring a same backlight sense, thereby reducing the production cost of the backlight product.

The present application provides a light-emitting diode, including:

a first semiconductor layer;

a light-emitting layer disposed on the first semiconductor layer;

a second semiconductor layer disposed on a side of the light-emitting layer away from the first semiconductor layer, and on a light-emitting surface of the light-emitting layer; and

a first protective layer disposed on a side of the second semiconductor layer away from the light-emitting layer;

wherein, a surface of the second semiconductor layer away from the light-emitting layer is a first diffusion surface, the first diffusion surface includes a first central curved surface and a first edge curved surface connected to the first central curved surface, the first central curved surface is concave towards the light-emitting layer, and the first edge curved surface is convex towards the light-emitting layer.

Optionally, in some embodiments of the present application, the central curved surface covers a center of the light-emitting layer.

Optionally, in some embodiments of the present application, the second semiconductor layer includes a first bottom surface, and the first bottom surface is in contact with the light-emitting surface of the light-emitting layer and connected with the first edge curved surface.

Optionally, in some embodiments of the present application, the surface of the first protective layer away from the second semiconductor layer is a second diffusion surface, the second diffusion surface includes a second central curved surface and a second edge curved surface connected to the second central curved surface, the second central curved surface is concave towards the light-emitting layer, the second edge curved surface is convex towards the light-emitting layer;

the first protective layer further includes a second bottom surface, and the second bottom surface is in contact with the first diffusion surface and connected with the second edge curved surface.

The present application provides a light-emitting substrate, including a substrate and light-emitting diodes disposed on the substrate, each of the light-emitting diodes including:

a first semiconductor layer;

a light-emitting layer disposed on the first semiconductor layer;

a second semiconductor layer disposed on a side of the light-emitting layer away from the first semiconductor layer, and on a light-emitting surface of the light-emitting layer; and

a first protective layer disposed on a side of the second semiconductor layer away from the light-emitting layer;

wherein, a surface of the second semiconductor layer away from the light-emitting layer is a first diffusion surface, the first diffusion surface includes a first central curved surface and a first edge curved surface connected to the first central curved surface, the first central curved surface is concave towards the light-emitting layer, and the first edge curved surface is convex towards the light-emitting layer.

Optionally, in some embodiments of the present application, the light-emitting substrate further includes an encapsulation layer covering the light-emitting diodes, and a concave part concaving towards the light-emitting diodes is defined on a surface of the encapsulation layer away from the substrate.

Optionally, in some embodiments of the present application, the encapsulation layer includes a plurality of encapsulation parts, each of the encapsulation parts includes the concave part covering a center of each of the light-emitting diodes, a surface of the concave part away from the light-emitting diodes includes a divergent surface concaving towards the light-emitting diodes, and the divergent surface protrudes outwards from the substrate towards the light-emitting diodes.

Optionally, in some embodiments of the present application, the encapsulation layer covers an upper surface of the light-emitting diodes and fills an area between adjacent light-emitting diodes, and the concave part covers a center of each of the light-emitting diodes; a surface of the encapsulation layer away from the light-emitting diodes is wavy.

Optionally, in some embodiments of the present application, the light-emitting substrate further includes a lamp socket disposed on the substrate, the lamp socket includes a bottom surface, a first surface and a second surface respectively connected to the bottom surface, and the bottom surface is in contact with a surface of the substrate, an angle between the first surface and the bottom surface and an angle between the second surface and the bottom surface are all acute angles, and the first surface and the second surface are provided with at least one of the light-emitting diodes.

Optionally, in some embodiments of the present application, the angle between the first surface and the bottom surface is equal to the angle between the second surface and the bottom surface.

Optionally, in some embodiments of the present application, the lamp socket further includes a third surface, the third surface is connected between the first surface and the second surface, the third surface is parallel to the bottom surface, the third surface is provided with at least one of the light-emitting diodes.

Optionally, in some embodiments of the present application, the lamp socket extends from one end of the substrate to another end of the substrate, a plurality of the light-emitting diodes are disposed on the first surface and the second surface, and the light-emitting diodes on the first surface and the light-emitting diodes on the second surface are symmetrical.

The present application also provides a display device, including a liquid crystal display panel and a light-emitting substrate disposed on a side of the liquid crystal display panel, the light-emitting substrate includes a substrate and a plurality of light-emitting diodes disposed on the base, and each of the light-emitting diodes includes:

a first semiconductor layer;

a light-emitting layer disposed on the first semiconductor layer;

a second semiconductor layer disposed on a side of the light-emitting layer away from the first semiconductor layer, and on a light-emitting surface of the light-emitting layer; and

a first protective layer disposed on a side of the second semiconductor layer away from the light-emitting layer;

wherein, a surface of the second semiconductor layer away from the light-emitting layer is a first diffusion surface, the first diffusion surface includes a first central curved surface and a first edge curved surface connected to the first central curved surface, the first central curved surface is concave towards the light-emitting layer, and the first edge curved surface is convex towards the light-emitting layer.

Optionally, in some embodiments of the present application, the light-emitting substrate further includes an encapsulation layer covering the light-emitting diodes, a concave part concaving towards the light-emitting diodes is defined on a surface of the encapsulation layer away from the substrate.

Optionally, in some embodiments of the present application, the encapsulation layer includes a plurality of encapsulation parts, each of the encapsulation parts includes the concave part covering a center of each of the light-emitting diodes, a surface of the concave part away from the light-emitting diodes includes a divergent surface concaving towards the light-emitting diodes, and the divergent surface protrudes outwards from the substrate towards the light-emitting diodes.

Optionally, in some embodiments of the present application, the encapsulation layer covers an upper surface of the light-emitting diodes and fills an area between adjacent light-emitting diodes, the concave part covers the center of each of the light-emitting diodes; a surface of the encapsulation layer away from the light-emitting diodes is wavy.

Optionally, in some embodiments of the present application, the light-emitting substrate further includes a lamp socket disposed on the substrate, the lamp socket includes a bottom surface, a first surface and a second surface respectively connected to the bottom surface, and the bottom surface is in contact with a surface of the substrate, an angle between the first surface and the bottom surface and an angle between the second surface and the bottom surface are all acute angles, and the first surface and the second surface are provided with at least one of the light-emitting diodes.

Optionally, in some embodiments of the present application, the angle between the first surface and the bottom surface is equal to the angle between the second surface and the bottom surface.

Optionally, in some embodiments of the present application, the lamp socket further includes a third surface, the third surface is connected between the first surface and the second surface, the third surface is parallel to the bottom surface, the third surface is provided with at least one of the light-emitting diodes.

Optionally, in some embodiments of the present application, the lamp socket extends from one end of the substrate to another end of the substrate, a plurality of the light-emitting diodes are disposed on the first surface and the second surface, and the light-emitting diodes on the first surface and the light-emitting diodes on the second surface are symmetrical.

### Advantageous Effects

Compared with the light-emitting diode in the prior art, in the present application, the surface of the second semiconductor layer away from the light-emitting layer is set as the first diffusion surface. Since the first diffusion surface includes the first central curved surface and the first edge curved surface connected to the first central curved surface, the first central curved surface is concave towards the light-emitting layer, and the first edge curved surface is convex towards the light-emitting layer. After a light emitted by the light-emitting layer enters the central surface and edge surface of the diffusion surface, an exit angle of the light emitted from the central surface and edge surface will increase, which can increase a light-emitting angle of the light-emitting diode, so as to provide the light-emitting diode that can emit light at a wide-angle. When above-mentioned the wide-angle of the light-emitting diode is used in a backlight product, the present application can reduce the number of light-emitting diodes in the backlight product under a condition of ensuring a same backlight sense, thereby reducing a production cost of the backlight product.

### BRIEF DESCRIPTION OF DRAWINGS

In order to more clearly illustrate the embodiments or the technical solutions of the existing art, the drawings illustrating the embodiments or the existing art will be briefly described below. The drawings in the following description merely illustrate some embodiments of the present application. Other drawings may also be obtained by those skilled in the art according to these figures without paying creative work.

FIG. 1 is a schematic structural diagram of a light-emitting diode provided by the present application.

FIG. 2 is a schematic structural diagram of a light-emitting substrate provided in a first embodiment of the present application.

FIG. 3 is a schematic structural diagram of a light-emitting substrate provided in a second embodiment of the present application.

FIG. 4 is an optical path schematic structural diagram of a light-emitting substrate provided in the second embodiment of the present application.

FIG. 5 is a schematic structural diagram of a light-emitting substrate provided in a third embodiment of the present application.

FIG. 6 is a schematic structural diagram of a light-emitting substrate provided in a fourth embodiment of the present application.

FIG. 7 is a plan schematic structural diagram of the light-emitting substrate provided in the fourth embodiment of the present application.

FIG. 8 is a three-dimensional schematic structural diagram of a lamp socket shown in FIG. 7.

FIG. 9 is a schematic structural diagram of a light-emitting substrate provided in a fifth embodiment of the present application.

FIG. 10 is a plan schematic structural diagram of the light-emitting substrate provided in the fifth embodiment of the present application.

FIG. 11 is a schematic structural diagram of a light-emitting substrate provided in a sixth embodiment of the present application.

FIG. 12 is a three-dimensional schematic structural diagram of a lamp socket shown in FIG. 11.

FIG. 13 is a schematic structural diagram of a display device provided by the present application.

### DETAILED DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in the present application, all other embodiments obtained by those skilled in the art without creative work shall fall within the protection scope of this application. In addition, it should be understood that the specific implementations described here are only used to illustrate and explain the application and are not used to limit the present application. In the present application, if no explanation is made to the contrary, the orientation words used such as “upper” and “lower” generally refer to the upper and lower positions of the device in actual use or working state, and specifically refer to the drawing directions in the drawings; and “inner” and “outer” refer to the outline of the device.

An embodiment of the present application provides a light-emitting diode, a light-emitting substrate, and a display device. Detailed descriptions are given below. It should be noted that the order of description in the following embodiments is not meant to limit the preferred order of the embodiments.

The present application provides a light-emitting diode. The light-emitting diode includes a first semiconductor layer, a light-emitting layer, a second semiconductor layer, and a first protective layer. The light-emitting layer is disposed on the first semiconductor layer. The second semiconductor layer is disposed on a side of the light-emitting layer away from the first semiconductor layer and on a light-emitting surface of the light-emitting layer. The first protective layer is disposed on a side of the second semiconductor layer away from the light-emitting layer. Wherein a surface of the second semiconductor layer away from the light-emitting layer is a first diffusion surface. The first diffusion surface includes a first central curved surface and a first edge curved surface connected to the first central curved surface. The first central curved surface is concave towards the light-emitting layer, and the first edge curved surface is convex towards the light-emitting layer.

Thus, in the present application, the surface of the second semiconductor layer away from the light-emitting layer is set as the first diffusion surface. Since the first diffusion surface includes the first central curved surface and the first edge curved surface connected to the first central curved surface, the first central curved surface is concave towards the light-emitting layer, and the first edge curved surface is convex towards the light-emitting layer. After a light emitted by the light-emitting layer enters the first central curved surface and the first edge curved surface of the first diffusion surface, an exit angle of the light emitted from the first central surface and the first edge surface will increase, which can increase a light-emitting angle of the light-emitting diode, so as to provide the light-emitting diode that can emit light at a wide-angle. When the above-mentioned light-emitting diode capable of wide-angle illumination is used in a backlight product, the present application can reduce a number of the light-emitting diodes in the backlight product under a condition of ensuring a same backlight sense, thereby reducing production cost of the backlight product.

The light-emitting diode provided by the present application will be described in detail below through specific embodiments.

Referring to FIG. 1, a first example of the present application provides a light-emitting diode 10. The light-emitting diode 10 includes a substrate 1, a buffer layer 2, a first semiconductor layer 3, a light-emitting layer 4, a second semiconductor layer 5, a first protective layer 6, a second protective layer 7, a first electrode 8, and a second electrode 9.

Specifically, the substrate 1 may be a sapphire substrate, a gallium arsenide substrate, or a silicon-based substrate. In this embodiment, the substrate 1 is the sapphire substrate.

The buffer layer 2 is disposed on a side of the substrate 1. A material of the buffer layer 2 may include gallium nitride.

The first semiconductor layer 3 is disposed on a side of the buffer layer 2 away from the substrate 1. In this embodiment, the first semiconductor layer 3 is an N-type semiconductor layer, and a material of the N-type semiconductor layer includes N-type gallium nitride.

The light-emitting layer 4 is disposed on a side of the first semiconductor layer 3 away from the buffer layer 2. The light-emitting layer 4 includes a light-emitting surface. Wherein, the light-emitting layer 4 is a multi-quantum well structure, and the multi-quantum well structure may include a stacked structure of a gallium nitride layer (not shown in the figures) and an indium gallium nitride layer (not shown in the figures).

The second semiconductor layer 5 is disposed on a side away from the first semiconductor layer 4. The second semiconductor layer 5 is located on the light-emitting surface of the light-emitting layer 4. The second semiconductor layer 5 is a structure with a concave center and a convex edge. In this embodiment, the second semiconductor layer 5 is a p-type semiconductor layer, and a material of the p-type semiconductor layer includes p-type gallium nitride.

The first protective layer 6 is disposed on a side of the second semiconductor layer 5 away from the light-emitting layer 4. The first protective layer 6 is a structure with a concave center and a convex edge. A refractive index of the first protective layer 6 is less than a refractive index of the second semiconductor layer 5 and is greater than a refractive index of air. Wherein, a material of the first protective layer 6 may include one or more of silicon oxide, silicon nitride, and silicon oxynitride.

In this embodiment, the light-emitting diode 10 includes at least one diffusion surface. The at least one diffusion surface includes a surface of the second semiconductor layer 5 away from the light-emitting layer 4 and a surface of the first protective layer 6 away from the second semiconductor layer 5. Wherein, the diffusion surface includes a central curved surface and an edge curved surface connected to the first central curved surface. Wherein, the first edge curved surface is on a peripheral side of the central curved surface. The first central curved surface is concave towards the light-emitting layer 4. The first edge curved surface is convex towards the light-emitting layer 4.

Wherein, the at least one diffusion surface includes a first diffusion surface 51 and a second diffusion surface 61. The surface of the second semiconductor layer 5 away from the light-emitting layer 4 is the first diffusion surface 51. The surface of the first protective layer 6 away from the second semiconductor layer 5 is the second diffusion surface 61. It should be noted that, in some embodiments, the light-emitting diode 10 may also include only one of the first diffusion surface 51 and the second diffusion surface 61. In this case, the diffusion surface is the surface of the second semiconductor layer 5 away from the light-emitting layer 4 or the surface of the first protective layer 6 away from the second semiconductor layer 5, and details are not repeated here.

Specifically, the first diffusion surface 51 includes a first central curved surface 511 and a first curved edge surface 512 connected to the first curved central surface 511. The first curved edge surface 512 is located on a peripheral side of the first curved central surface 511. The first curved central surface 511 is concave towards the light-emitting layer 4. The first edge curved surface 512 is convex towards the light-emitting layer 4. Through the above arrangement, when a light emitted from a center of the light-emitting layer 4 enters the first central curved surface 511 and the first edge curved surface 512, the above incident light will be diffused in a direction away from the center of the light-emitting layer 4, the exit angle of the light can be increased, so that the light-emitting diode 10 can realize the wide-angle light emission.

In this embodiment, the first central curved surface 511 covers the center of the light-emitting layer 4, and this arrangement enables an outgoing light from the center of the light-emitting layer 4 to enter the first central curved surface 511 to increase a light-emitting viewing angle of the center of the light-emitting layer 4.

Further, the second semiconductor layer 5 further includes a first bottom surface 52. The first bottom surface 52 is in contact with the light-emitting surface of the light-emitting layer 4 and is connected to the first edge curved surface 512.

When the light emitted from the center of the light-emitting layer 4 enters the first central curved surface 511 and the first edge curved surface 512. The above incident light is diffused in a direction away from the center of the light-emitting layer 4 on the first central curved surface 511 and the first edge curved surface 512, respectively. Specifically, a part of the incident light will be refracted on the first central curved surface 511, and an angle of a refracted light will increase, so that a light-emitting viewing angle of a front of the light-emitting diode 10 can be increased. Another part of the incident light is reflected on front surfaces of the first central curved surface 511 and the first edge curved surface 512 and is directed to side surfaces of the first edge curved surface 512. The reflected light directed to the side surfaces of the first edge curved surface 512 will be refracted, so that an angle of the refracted light emitted from the side surfaces of the first edge curved surface 512 increases, thereby increasing the light-emitting viewing angle of the light-emitting diode 10. Thus, the embodiment provides the light-emitting diode 10 capable of a wide-angle light emission.

Specifically, the second diffusion surface 61 includes a second central curved surface 611 and a second edge curved surface 612 connected to the second central curved surface 611. Wherein, the second edge curved surface 612 is located on a peripheral side of the second central curved surface 611. The second central curved surface 611 is concave towards the light-emitting layer 4. The second edge curved surface 612 is convex towards the light-emitting layer 4. Through the above arrangement, when the light emitted from the first diffuse surface 51 enters the second central curved surface 611 and the second edge curved surface 612, the incident light is diffused in a direction away from the center of the light-emitting layer 4, so that the exit angle of the light can be further increased.

In the embodiment, the second central curved surface 611 covers the center of the light-emitting layer 4, and this arrangement enables an outgoing light from the center of the light-emitting layer 4 to exit from the first central surface 511 and then enter the second central surface 611, so as to further increase the light-emitting viewing angle of the center of the light-emitting layer 4.

Further, the first protective layer 6 further includes a second bottom surface 62. The second bottom surface 62 is in contact with the first diffusion surface 51 and connected with the second edge curved surface 612.

When the light emitted from the center of the light-emitting layer 4 exits from the first central curved surface 511 and the first edge curved surface 512 and then enters the second central curved surface 611 and the second edge curved surface 612, the above incident light is diffused in a direction away from the center of the light-emitting layer 4 on the second central curved surface 611 and the second edge curved surface 612 respectively. Specifically, a part of the incident light will be refracted on the second central curved surface 611, and the angle of a refracted light will increase, so that the light-emitting viewing angle of the front of the light-emitting diode 10 can be further increased. Another part of the incident light will be reflected on front surfaces of the second central curved surface 611 and the second edge curved surface 612 and is directed to side surfaces of the second edge curved surface 612. The reflected light directed to the side surfaces of the second edge curved surface 612 will be refracted, so that the angle of the refracted light emitted from the side surfaces of the second edge curved surface 612 increases, thereby further increasing the light-emitting viewing angle of the light-emitting diode 10. Therefore, an overall light-emitting viewing angle of the light-emitting diode 10 is increased.

The second protective layer 7 is disposed on a side of the first semiconductor layer 3 away from the buffer layer 2 and adjacent to the light-emitting layer 4. A thickness of the second protective layer 7 is less than a thickness of the light-emitting layer 4. Specifically, the second protective layer 7 is a same layer as the light-emitting layer 4, and a side of the second protective layer 7 is in contact with a side of the light-emitting layer 4. Wherein, the second protective layer 7 can be prepared by a same process as the first protective layer 6, and a material of the second protective layer 7 can include one or more of silicon oxide, silicon nitride and silicon oxynitride.

The first electrode 8 is disposed on a side of the first protective layer 6 away from the second semiconductor layer 5, and the first electrode 8 may be a p-type electrode. The second electrode 9 is disposed on a side of the second protective layer 7 away from the first semiconductor layer 3, and the second electrode 9 may be an n-type electrode. It should be noted that, the first electrode 8 can be disposed on the second edge curved surface 612 or the second central curved surface 611. This application only illustrates a structure when the first electrode 8 is disposed on the second edge curved surface 612, but it should not be construed as a limitation of the application.

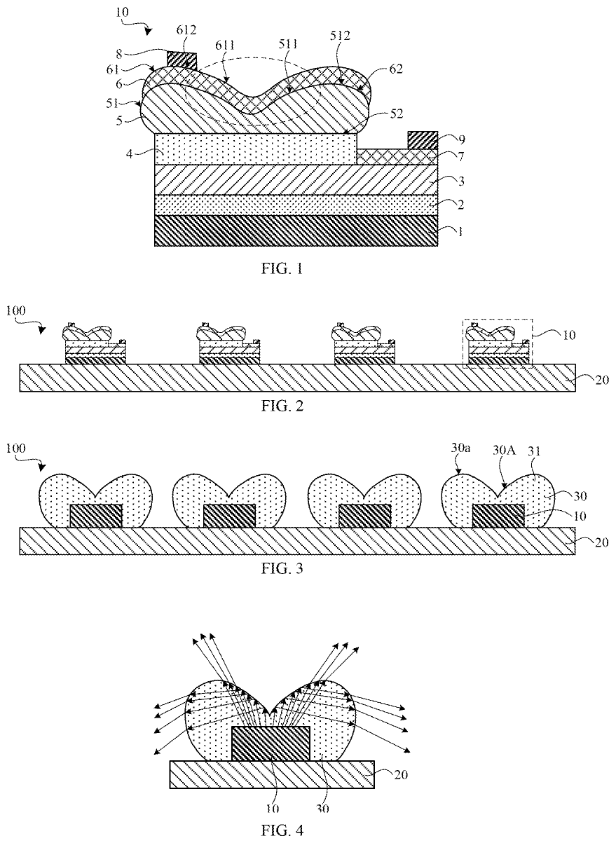

Referring to FIG. 2, a first embodiment of the present application provides a light-emitting substrate 100. The light-emitting substrate 100 includes a substrate 20 and light-emitting diodes 10 disposed on the substrate 20.

Wherein, the substrate 20 may be a driving substrate, and the driving substrate may be a PCB-based driving substrate or a glass-based driving substrate. In addition, a structure of the light-emitting diodes 10 is a same as a structure of the light-emitting diodes 10 in the first example of the foregoing, and a specific structure of the light-emitting diodes 10 can refer to a description of the first example of the foregoing, which is not repeated here.

It should be noted that, the light-emitting substrate 100 provided in the embodiments can be applied to an LCD as the backlight product and can also be used as a direct-display product. The embodiments only take the light-emitting substrate 100 as the backlight product for illustration, but it is not understood that to limit this application.

The light-emitting substrate 100 provided in the embodiment uses 10 the light-emitting diodes of the wide-angle light emission, the number of the light-emitting diodes 10 in the light-emitting substrate 100 can be reduced under the condition of ensuring the same backlight sense, thereby reducing the production cost of the backlight product. In addition, the embodiment can improve the backlight sense while ensuring that the number of the light emitting diodes 10 in the light-emitting substrate 100 is the same, so as to improve a contrast ratio of a display product.

Referring to FIG. 3 and FIG. 4, a second embodiment of the present application provides a light-emitting substrate 100. The difference between the light-emitting substrate 100 provided in the second embodiment of the present application and the first embodiment is that the light-emitting substrate 100 further includes an encapsulation layer 30 covering the light-emitting diodes 10. A concave port 30A concaving towards the light-emitting diode 10 is defined on a surface of the encapsulation layer 30 away from the substrate 20.

In this embodiment, the encapsulation layer 30 includes a plurality of encapsulation parts 31. Wherein, a material of the encapsulation parts 31 may include one or more of epoxy resin, acrylic resin, and silica gel.

Each of the encapsulation parts 31 includes the concave part 30A covering the center of each of the light-emitting diodes 10. A surface of the concave part 30A away from the light-emitting diodes 10 includes a divergent surface 30a concaving towards the light-emitting diodes 10. The divergent surface 30a protrudes outwards from the substrate 20 towards the light-emitting diodes 10.

It should be noted that, a structure of the diverging surface 30a is same as a structure of the first diffusing surface 51 in the first example of the foregoing, and a principle of increasing the exit angle of the light is also same. A description of the first diffusion surface 51 will not be repeated here.

In this embodiment, by disposing the diverging surface 30a on each of the encapsulation parts 31, when the light emitted from the center of the light-emitting diodes 10 enters the diverging surface 30a, the above incident light is diffused in a direction away from the center of the light-emitting diodes 10 on the diverging surface 30a. Specifically, a part of the incident light will be refracted on the diverging surface 30a, and the angle of the refracted light will increase, so that the light-emitting viewing angle of the front of the light-emitting diode 10 can be increased. Another part of the incident light will be reflected on the diverging surface 30a and enter sides of the encapsulation parts 31, and the reflected light will be refracted on sides of the encapsulation layer 30, so that the angle of the refracted light emitted from the sides of the encapsulation part 31 increases, thereby increasing the light-emission viewing angle of the side of the light-emitting diode 10. Therefore, by arranging the encapsulation ports 31 including the above structure on the light-emitting diodes 10, the present embodiment can further increase the light-emitting viewing angle above and on the side of the light-emitting diodes 10 on the light-emitting substrate 100, so as to ensure the same backlight sense. The number of light-emitting diodes 10 in the light-emitting substrate 100 is further reduced so as to further reduce the production cost of the backlight product.

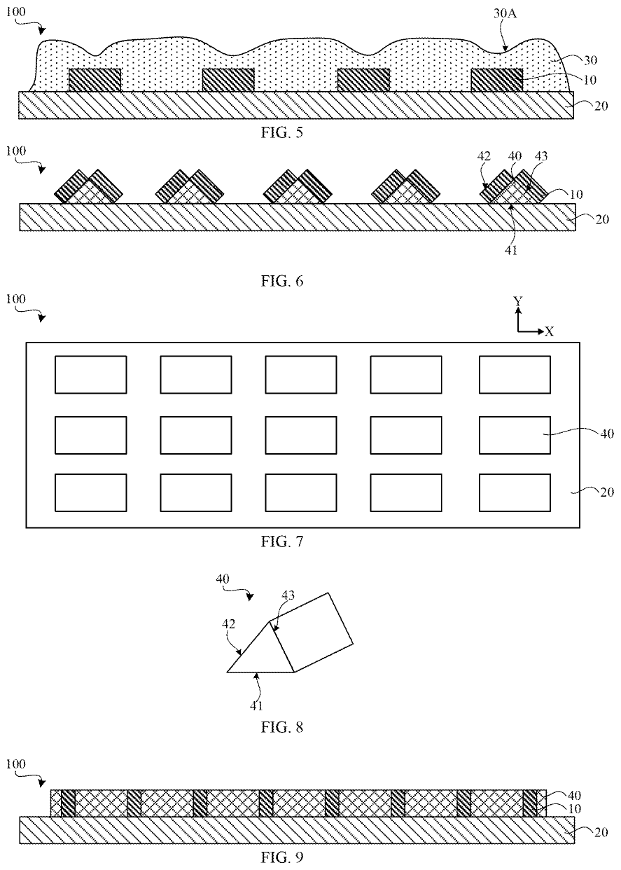

Referring to FIG. 5, a third embodiment of the present application provides a light-emitting substrate 100. The difference between the light-emitting substrate 100 provided in the third embodiment of the present application and the first embodiment is that the light-emitting substrate 100 further includes the encapsulation layer 30 covering the light-emitting diode 10. The concave port 30A concaving towards the light-emitting diode 10 is defined on the surface of the encapsulation layer 30 away from the substrate 20.

Specifically, the encapsulation layer 30 disposed on an entire surface. Wherein, a material of the encapsulation layer 30 may include one or more of epoxy resin, acrylic resin, and silica gel.

The encapsulation layer 30 covers an upper surface of the light-emitting diodes 10 and fills an area between adjacent light-emitting diodes 10. The concave part 30A covers the center of each of the light-emitting diodes 10. The surface of the encapsulation layer 30 away from the light-emitting diodes 10 is wavy.

It should be noted that, in this embodiment, a portion of the surface of the encapsulation layer 30 away from the substrate 20 corresponding to the light-emitting diodes 10 is concave towards the substrate 20 to define the concave part 30A corresponding to each of the light-emitting diodes 10. In a region between adjacent light-emitting diodes 10, the surface of the encapsulation layer 30 away from the substrate 20 protrudes towards the substrate 20.

In this embodiment, when the light emitted from the center of the light-emitting diodes 10 enters the surface of the encapsulation layer 30, the above incident light is diffused in a direction away from the center of the light-emitting diodes 10 at the concave part 30A. Specifically, a part of the incident light will be refracted on the surface of the concave part 30A, and the angle of the refracted light will increase, so that the light-emitting viewing angle of the front of the light-emitting diode 10 can be increased. The number of light-emitting diodes 10 in the light-emitting substrate 100 can be further reduced under a condition of ensuring a same backlight sense, so as to further reduce the production cost of the backlight product.

Referring to FIGS. 6 to 8, a fourth embodiment of the present application provides a light-emitting substrate 100. The light-emitting substrate 100 provided in the fourth embodiment of the present application is different from the first embodiment in that the light-emitting substrate 100 further includes a lamp socket 40 disposed on the substrate 20. The lamp socket 40 includes a bottom surface 41, and a first surface 42 and a second surface 43 respectively connected to the bottom surface 41. The bottom surface 41 is in contact with a surface of the substrate 20. An angle between the first surface 42 and the bottom surface 41 and an angle between the second surface 43 and the bottom surface 41 are all acute angles. The first surface 42 and the second surface 43 are disposed with at least one of the light-emitting diodes 10.

In the embodiments, by arranging the lamp socket 40 on the substrate 20, since the angle between the first surface 42 and the bottom surface 41 and the angle between the second surface 43 and the bottom surface 41 of the socket holder 40 are all acute angles, for a same lamp socket 40, by using the lamp socket 40 as a carrier, so that the light-emitting diodes 10 are disposed obliquely, thereby increasing the light-emitting viewing angle above the lamp holder 40, thereby further increasing the light-emitting viewing angle of the light-emitting substrate 100 and improving the backlight sense. In addition, when a size of the light-emitting substrate 100 is fixed, under the above-mentioned setting, a larger number of light-emitting diodes 10 can be accommodated on the substrate 20, so that the backlight sense can be further improved.

It should be noted that, this embodiment only takes a structure when the number of the light-emitting diodes 10 on the first surface 42 and the second surface 43 is one for description as an example but is not limited to this. In some embodiments, the number of the light-emitting diodes 10 on the first surface 42 and the second surface 43 may be two or more, a specific number of the light-emitting diodes 10 on the first surface 42 and the second surface 43 can be set according to actual application requirements, which is not limited in this application.

In some specific embodiments, the angle between the first surface 42 and the bottom surface 41 and the angle between the second surface 43 and the bottom surface 41 may be 30 degrees, 45 degrees or 60 degrees, and a specific size of the above-mentioned included angles can also be adjusted according to the light-emitting angle of the light-emitting diodes 10, which is not limited in this application.

Further, in the embodiments, the angle between the first surface 42 and the bottom surface 41 is equal to the angle between the second surface 43 and the bottom surface 41. The above arrangement can improve uniformity of light emission above the socket 40, which is beneficial to improve the uniformity of light emission of entire the light-emitting substrate 100.

In this embodiment, a plurality of lamp sockets 40 are arranged in an array on the substrate 20, as shown in FIG. 7. Wherein, in a first direction X and a second direction Y, a number of lamp sockets 40 is multiple. Specifically, as shown in FIG. 8, each of the lamp sockets 40 may be a triangular prism structure. In addition, the light-emitting diodes 10 on the first surface 42 and the light-emitting diodes 10 on the second surface 43 are symmetrical, and this arrangement can improve the light-emitting uniformity above the lamp socket 40.

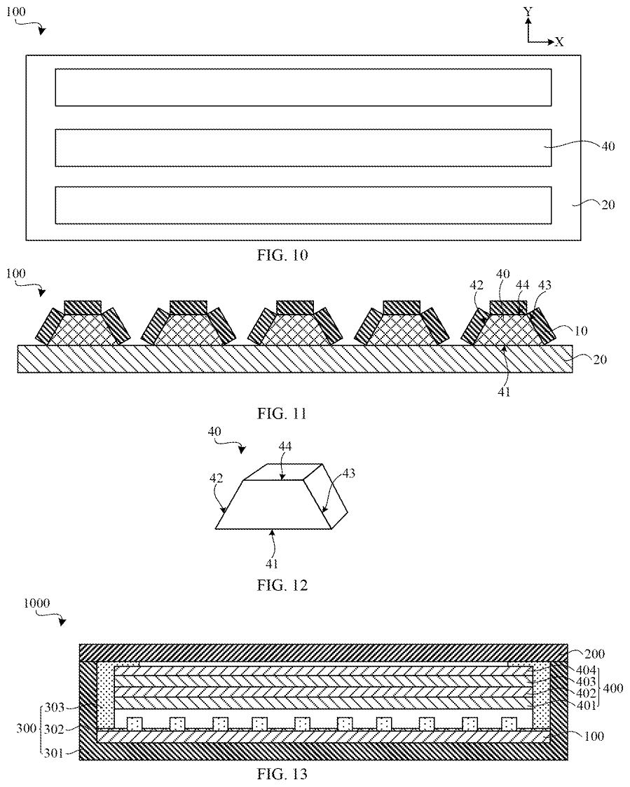

Referring to FIG. 9 and FIG. 10, a fifth embodiment of the present application provides a light-emitting substrate 100. The light-emitting substrate 100 provided in the fifth embodiment of the application is different from the fourth embodiment in that the lamp socket 40 extends from one end of a substrate 20 to another end of the substrate 20. A plurality of the light-emitting diodes 10 are arranged on both the first surface 42 and the second surface 43.

Specifically, in the first direction X, the number of the lamp sockets 40 is one, and in the second direction Y, the number of the lamp sockets 40 is multiple.

In the embodiments, by setting the number of the lamp sockets 40 in the first direction X as one, the number of the lamp sockets 40 greatly reduced, thereby reducing the difficulty of a process operation of the light-emitting substrate 100. In addition, when a size of the light-emitting substrate 100 is fixed, a larger number of light-emitting diodes 10 can be accommodated on one of the lamp sockets 40, thereby improving backlight sense.

It should be noted that, in some embodiments, the number of the lamp sockets 40 in the second direction Y may also be one, and the number of the lamp sockets 40 in the first direction X may be set to multiple, which will not be repeated here.

Referring to FIG. 11 and FIG. 12, a sixth embodiment of the present application provides a light-emitting substrate 100. The difference between the light-emitting substrate 100 provided in the sixth embodiment of the present application and the fourth embodiment is that the lamp socket 40 further includes a third surface 44. The third surface 44 is connected between the first surface 42 and the second surface 43. The third surface 44 is parallel to the bottom surface 41. At least one of the light-emitting diodes 10 is disposed on the third surface 44.

In the embodiments, by arranging the lamp socket 40 including the third surface 44, the light-emitting diodes 10 can be accommodated on the third surface 44, thereby increasing the light-emitting viewing angle of the light-emitting substrate 100 and increasing the light emitting angle directly above the lamp socket 40. The light-emitting brightness is to improve the light-emitting brightness of the front surface of the light-emitting substrate 100.

It should be noted that, in the embodiments, only one case where the number of the light-emitting diodes 10 on the third surface 44 is one is used as an example for description, but not limited to this. In some embodiments, the number of the light-emitting diodes 10 on the third surface 44 may be two or more, and the specific number of light-emitting diodes 10 on the third surface 44 may be set according to actual application requirements, which is not limited in this application.

The present application also provides a display device. Wherein, the display device may be any product or component including display function, such as electronic paper, mobile phone, tablet computer, television, monitor, notebook computer, digital photo frame, navigator, etc.

Specifically, please refer to FIG. 13, the display device 1000 provided by the present application includes a liquid crystal display panel 200 and a light-emitting substrate 100 disposed on one side of the liquid crystal display panel 200. The light-emitting substrate 100 may be the light-emitting substrate 100 described in any of the foregoing embodiments, and specific structure of the light-emitting substrate 100 may refer to the description of any of the foregoing embodiments, which will not be repeated here.

Further, the display device 1000 further includes a frame body 300 and an optical module 400. Specifically, the frame body 300 includes a bottom plate 301, a side wall 302, and a middle frame 303. The bottom plate 301 is disposed on a side of the light-emitting substrate 100 away from the liquid crystal display panel 200 and is used for supporting the light-emitting substrate 100. The side wall 302 is disposed on the bottom plate 301 and connected to the bottom plate. The middle frame 303 is disposed on the side wall 302. The optical module 400 is in contact with an inner surface of the middle frame 303. Wherein, the optical module 400 may include a diffuser plate 401, a diffuser sheet 402, a quantum dot film 403 and a prism sheet 404 that are sequentially arranged above the light-emitting substrate 100.

It should be noted that, a structure of the display device 1000 in this embodiment is only for illustration and is used to facilitate the description of this embodiment. In some embodiments, the display device 1000 may further include other film layer structures, which will not be repeated here.

The above describes in detail a light-emitting diode, a light-emitting substrate and a display device provided by the embodiments of the present application. Specific examples are used in the present application to illustrate the principles and implementation of this application. The descriptions of the above examples are only used to help understand the methods and core ideas of the present application; at the same time, according to the principles of the present application, those skilled in the art will have changes in the thinking, specific implementation, and application scope. In summary, the content of this specification should not be construed as a limitation to the present application.

What is claimed is:

1. A light-emitting diode, comprising:
a first semiconductor layer;
a light-emitting layer disposed on the first semiconductor layer;
a second semiconductor layer disposed on a side of the light-emitting layer away from the first semiconductor layer, and on a light-emitting surface of the light-emitting layer; and
a first protective layer disposed on a side of the second semiconductor layer away from the light-emitting layer;
wherein, a surface of the second semiconductor layer away from the light-emitting layer is a first diffusion surface, the first diffusion surface comprises a first central curved surface and a first edge curved surface connected to the first central curved surface, the first central curved surface is concave towards the light-emitting layer, and the first edge curved surface is convex towards the light-emitting layer.

2. The light-emitting diode according to claim 1, wherein the central curved surface covers a center of the light-emitting layer.

3. The light-emitting diode according to claim 1, wherein the second semiconductor layer comprises a first bottom surface, and the first bottom surface is in contact with the light-emitting surface of the light-emitting layer and connected with the first edge curved surface.

4. The light-emitting diode according to claim 3, wherein the surface of the first protective layer away from the second semiconductor layer is a second diffusion surface, the second diffusion surface comprises a second central curved surface and a second edge curved surface connected to the second central curved surface, the second central curved surface is concave towards the light-emitting layer, the second edge curved surface is convex towards the light-emitting layer;
the first protective layer further comprises a second bottom surface, and the second bottom surface is in contact with the first diffusion surface and connected with the second edge curved surface.

5. A light-emitting substrate, comprising a substrate and light-emitting diodes disposed on the substrate, the light-emitting diodes being the light-emitting diodes according to claim 1.

6. The light-emitting substrate according to claim 5, wherein the light-emitting substrate further comprises an encapsulation layer covering the light-emitting diodes, and a concave part concaving towards the light-emitting diodes is defined on a surface of the encapsulation layer away from the substrate.

7. The light-emitting substrate according to claim 6, wherein the encapsulation layer comprises a plurality of encapsulation parts, each of the encapsulation parts comprises the concave part covering a center of each of the light-emitting diodes, a surface of the concave part away from the light-emitting diodes comprises a divergent surface concaving towards the light-emitting diodes, and the divergent surface protrudes outwards from the substrate towards the light-emitting diodes.

8. The light-emitting substrate according to claim 6, wherein the encapsulation layer covers an upper surface of the light-emitting diodes and fills an area between adjacent light-emitting diodes, and the concave part covers a center of each of the light-emitting diodes; a surface of the encapsulation layer away from the light-emitting diodes is wavy.

9. The light-emitting substrate according to claim 5, wherein the light-emitting substrate further comprises a lamp socket disposed on the substrate, the lamp socket comprises a bottom surface, a first surface and a second surface respectively connected to the bottom surface, and the bottom surface is in contact with a surface of the substrate, an angle between the first surface and the bottom surface and an angle between the second surface and the bottom surface are all acute angles, and the first surface and the second surface are provided with at least one of the light-emitting diodes.

10. The light-emitting substrate according to claim 9, wherein the angle between the first surface and the bottom surface is equal to the angle between the second surface and the bottom surface.

11. The light-emitting substrate according to claim 9, wherein the lamp socket further comprises a third surface, the third surface is connected between the first surface and the second surface, the third surface is parallel to the bottom surface, the third surface is provided with at least one of the light-emitting diodes.

12. The light-emitting substrate according to claim 9, wherein the lamp socket extends from one end of the substrate to another end of the substrate, a plurality of the light-emitting diodes are disposed on the first surface and the second surface, and the light-emitting diodes on the first surface and the light-emitting diodes on the second surface are symmetrical.

13. A display device, comprising a liquid crystal display panel and a light-emitting substrate disposed on a side of the liquid crystal display panel, the light-emitting substrate being the light-emitting substrate according to claim 5.

14. The display device according to claim 13, wherein the light-emitting substrate further comprises an encapsulation layer covering the light-emitting diodes, a concave part concaving towards the light-emitting diodes is defined on a surface of the encapsulation layer away from the substrate.

15. The display device according to claim 14, wherein the encapsulation layer comprises a plurality of encapsulation parts, each of the encapsulation parts comprises the concave part covering a center of each of the light-emitting diodes, a surface of the concave part away from the light-emitting diodes comprises a divergent surface concaving towards the light-emitting diodes, and the divergent surface protrudes outwards from the substrate towards the light-emitting diodes.

16. The display device according to claim 14, wherein the encapsulation layer covers an upper surface of the light-emitting diodes and fills an area between adjacent light-emitting diodes, the concave part covers the center of each of the light-emitting diodes; a surface of the encapsulation layer away from the light-emitting diodes is wavy.

17. The display device according to claim 13, wherein the light-emitting substrate further comprises a lamp socket disposed on the substrate, the lamp socket comprises a bottom surface, a first surface and a second surface respectively connected to the bottom surface, and the bottom surface is in contact with a surface of the substrate, an angle between the first surface and the bottom surface and an angle between the second surface and the bottom surface are all acute angles, and the first surface and the second surface are provided with at least one of the light-emitting diodes.

18. The display device according to claim 17, wherein the angle between the first surface and the bottom surface is equal to the angle between the second surface and the bottom surface.

19. The display device according to claim 17, wherein the lamp socket further comprises a third surface, the third surface is connected between the first surface and the second surface, the third surface is parallel to the bottom surface, the third surface is provided with at least one of the light-emitting diodes.

20. The display device according to claim 17, wherein the lamp socket extends from one end of the substrate to another end of the substrate, a plurality of the light-emitting diodes are disposed on the first surface and the second surface, and the light-emitting diodes on the first surface and the light-emitting diodes on the second surface are symmetrical.
